(19) United States
(12) Patent Application Publication
(10) Pub. No.: US 2011/0255224 A1
(43) Pub. Date: Oct. 20, 2011

(54) ELECTRIC COMPONENT AND PIN HEADER FOR SUCH A COMPONENT

(76) Inventors: Hans Van Woensel, Rosmalen (NL); Thierry Goossens, Herdersem-Aalst (BE)

(21) Appl. No.: 12/998,598

(22) PCT Filed: Nov. 7, 2008
(86) PCT No.: PCT/IB2008/055640

§ 371 Date: Jun. 27, 2011

(51) Int. Cl. H05K 7/00; B29C 45/14

(52) U.S. Cl. 361/679.01; 264/272.14

(57) ABSTRACT

The invention relates to an electric component and a pin header. The component includes a first member including a first side and a second side, wherein the first member includes one or more openings extending between the first side and the second side. A body portion of moulding material is provided on the first side of the first member. A frame containing one or more electrical leads extending from the frame through the corresponding openings of the first member is provided, such that the first member and the frame cooperate to substantially closes said openings around one or more of said one or more electrical leads. Consequently, moulding material cannot pass through the openings.

### FIELD OF THE INVENTION

The invention is in the field of electronics. More specifically, the invention relates to an electric component, a pin header and a method of manufacturing such a component.

### BACKGROUND OF THE INVENTION

In the field of electronics, electric components are nowadays expected to meet a variety of requirements regarding ease of manufacturing, life expectancy, ease of repair or replacement, design aspects etc. Since many of such electric components are bulk products, such as light components (LED's) or sensor components, the costs of such components are also critical.

Moulding is a well known and advantageous technique for manufacturing (parts of) such electric components. Typically, a polymer is used as a moulding material. During a moulding step of a part of the electric component, the moulding material may get poured into undesired places of the product due to pressure and the viscous nature of the moulding material.

### SUMMARY OF THE INVENTION

It is an object of the invention to provide an improved product and method that reduces the probability the moulding material ends up in undesired places in the product.

Aspects of the invention are defined in claims 1, 9, 10, 11 and 15.

By appropriate structuring of at least one of the first member and the frame, the leads of the frame may extend through the corresponding openings in the first member, while the remaining part of these lead openings is substantially closed by the structures before moulding. As a consequence, during moulding, moulding material cannot leak through the opening along the leads to undesired places in the electric component.

The moulding material is advantageously injected under low pressure, e.g. below 20 atmospheres or below 10 atmospheres, in order to further reduce the probability of undesired leakage of moulding material. The moulding material may have a lower melting point than the melting point of the frame material.

The embodiment of the invention according to claim 2 provides for an appropriate protection of the frame and a major part of the leads from the environment and to provide a mechanically strong component.

The embodiment of the invention according to claim 3 allows the frame to determine the distance between the first and second member, i.e. the frame has a spacer function. Consequently, the frame (and not the leads) carries the force exerted on the second member during moulding.

The structures may close each opening individually, as defined or multiple holes. Closing each opening individually is applicable if the pitch of the leads is sufficiently large to allow a corresponding structure around each lead. Structures surrounding multiple leads can be applied for smaller pitches.

The embodiments of the invention as defined in claims 7 and 13 save material and reduce the weight of the frame. Moreover, the insertion force for inserting the leads into openings of the frame is reduced.

The embodiments of the invention as defined in claims 4 and 14 provides for an appropriate contact force of the leads against the second member (before installation, the leads extend further from the frame than the stand-off structures), while in the installed position the stand-off structures abut against the second member to carry forces exerted on the second member.

The embodiment of claim 8 allows for easy replacement of the electronic component upon malfunction.

The invention will hereafter be more fully explained with reference to the drawings showing different embodiments of the invention by way of example.

### BRIEF DESCRIPTION OF THE DRAWINGS

FIGS. 1A and 1B provide schematic illustrations of part of an electric component according to an embodiment of the invention;

FIGS. 2A and 2B show an electric product and a pin header according to an embodiment of the invention;

FIGS. 3A-3E show further views of the electric product and pin header of FIGS. 2A and 2B.

FIGS. 4A and 4B show pin headers according to further embodiments of the invention.

### DETAILED DESCRIPTION OF THE DRAWINGS

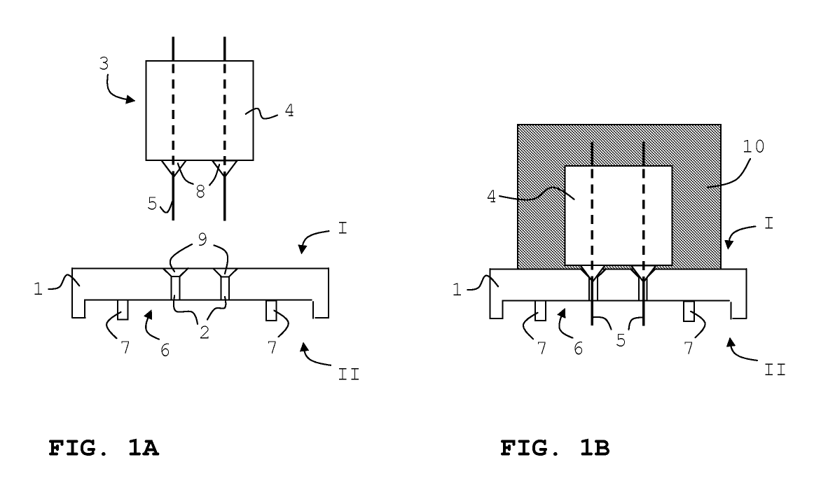

FIGS. 1A and 1B show schematic illustrations of part of the electric component according to an embodiment of the invention.

The electric component has a planar first member 1 made of plastic having a first side I and a second side II through which openings 2 extend.

The first side I is intended for positioning a connector header 3 comprising a frame 4 with leads or pins 5, also referred to as pin header. The second side II has a space 6 wherein means 7 for locking and unlocking a connector (not shown) are provided in order to allow replacement of the electric component.

The latter connector can be connected to the leads 5 by positioning the pin header 3 on the first member as illustrated in FIG. 1B. In order to fix the pin header 3 in place in respect to the first member 1 and further protect it from external environment, a moulding material is casted around the pin header 3. In doing so, structures 8 provided on the frame 4 interfere with corresponding structure 9 provided in the openings 2 of the first member 1. These interfering structures 8, 9 avoid that moulding material 10 may leak through the openings 2 into the space 6 during low-pressure moulding, thereby covering the exposed portions of the pins 5 in this space. Structure 9 may also be shaped to facilitate insertion of the leads 5 into openings 2.

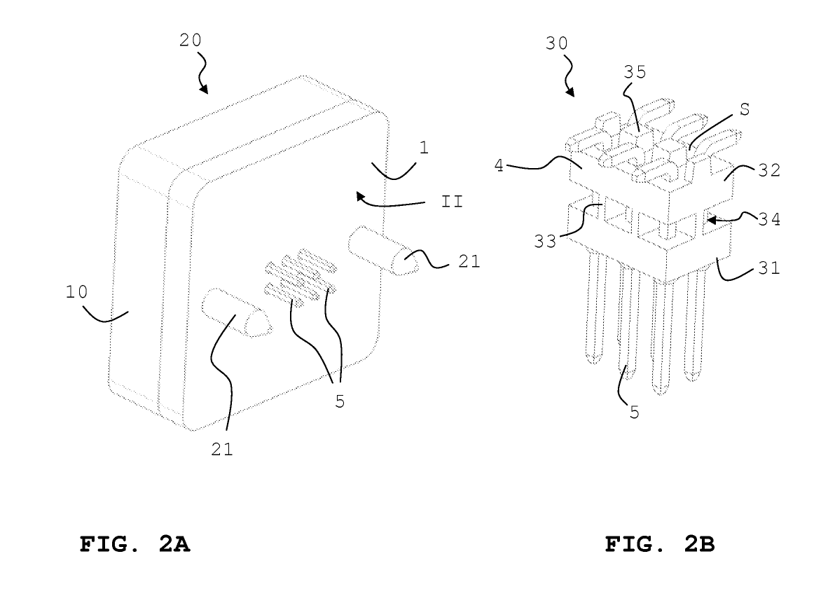

FIGS. 2A and 2B respectively show an electric component 20 and a 6-pin header 30 according to an embodiment of the invention. Corresponding reference numbers have been used to indicate parts similar to the parts of FIGS. 1A and 1B.

Examples of electric components include light-emitting devices for e.g. a video wall or sensors. Such electronic products are typically connected to a connector having contact corresponding to the leads 5 of the pin header 3. Guiding poles 21 are provided to facilitate such connection. It should be noted that locking means 7, as indicated in space 6 of FIG. 1A, may also be provided on side II of the first member 1.

The pin header 30 of FIG. 2B comprises a plastic frame 4 and six pins 5. The plastic frame 4 is a moulded component comprising a first portion 31 and a second portion 32 separated by walls 33 leaving spaces 34 in between the walls 33. The pins 5 extend between the walls 33 through the spaces 34.

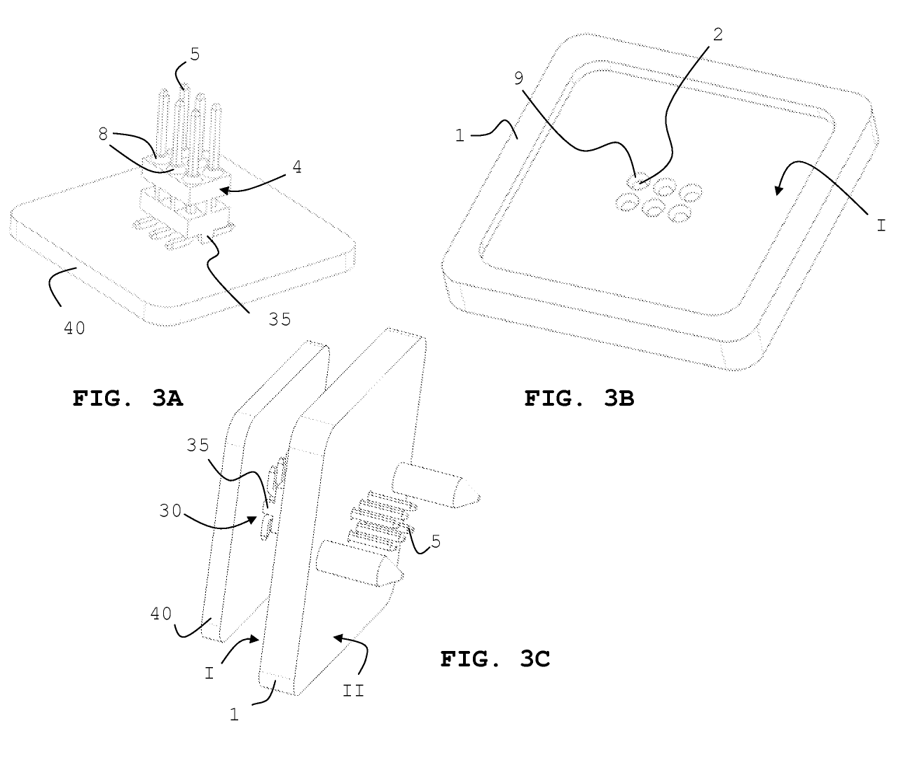

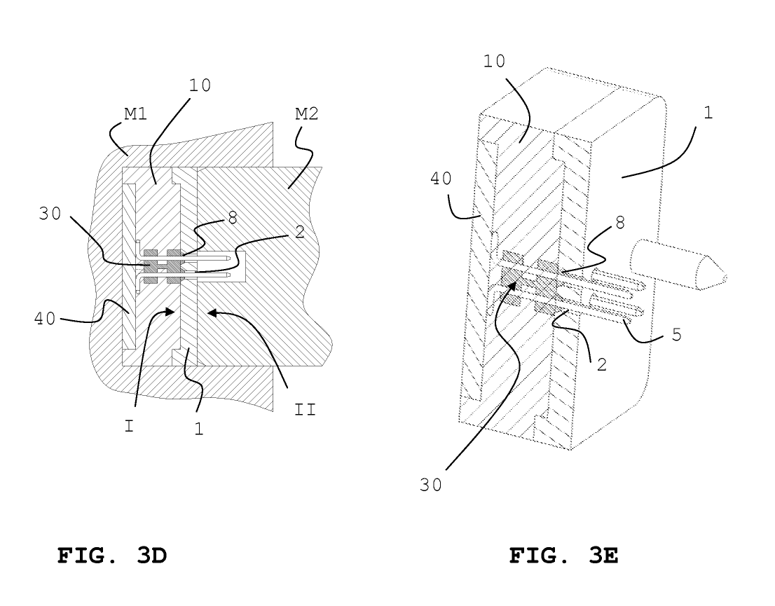

The first portion 31, intended to face the first member 1 of the electric component, is provided with the cone-shaped structures 8 around each of the leads 5 (See FIG. 3A). The sec- and portion 32 comprises stand-off structures 35 intended to abut against a second member as will be described in further detail with reference to FIGS. 3A-3E. The frame 4 may have a height of e.g. 10 mm.

The pin header 30 may be produced by moulding the plastic frame 4 in an appropriate mould, followed by inserting the pins 5 and bending them at the second portion 32. Bending is performed such that the bent portions extend a little further from the surface S of the second portion than the end surfaces of the stand-off structures 35. The pins 5 may also be insert-moulded in the frame 4.

FIGS. 3A-3E show further views of the electric component 20 and pin header 30 of FIGS. 2A and 2B.

FIG. 3A shows the pin header 30 on a second planar member 40 of the electric component 20. The second planar member may e.g. carry a printed circuit board or other electric arrangement and may further contain a functional component, such as a sensor or a light emitting device (e.g. a light emitting diode), possibly in combination with an optical component, such as a lens.

As a result of bending the leads 5 as described above, a good electrical connection between the leads 5 and contacts (not shown) of the second member 40 is guaranteed, while the abutment of the stand-off structures 35 against the surface of the second member 40 ensures that forces exerted on the second member are carried by the frame 4.

Clearly, each of the leads 5 is surrounded individually by a cone-like structure 8.

FIG. 3B shows the first member 1 of the electric component 20 from the first side I. The openings 2 are structured such that the cone-like structures 8 of header frame 4 interfere (or engage) with these openings 2 when the header 30 is positioned on the first member 1 as shown in FIG. 3C. In FIG. 3C, the height of the frame 4 determines the separation between the first and second members 1, 40.

Subsequently, as illustrated in FIG. 3D, the moulding material 10 is provided under low pressure (e.g. less than 10 atmospheres) using mould components M1 and M2 to overmould frame 4. The interference between structures 8 and the shapes of the openings 2 avoids that during this moulding step, moulding material leaks through the openings. FIG. 3E provides a cross-section of the electric component 20. It should be noted that moulding material 10 may also (partially) accommodate the second member 40.

It should be noted that the header 30 and the second member 40 may abut each other for example via the bent part of the pins and/or or the stand-off structures 35 so as to press in the mould the surface of the header or structures 8 against the corresponding surface of the first component. Controlling this pressure avoid leaks of material 10 through the openings 2.

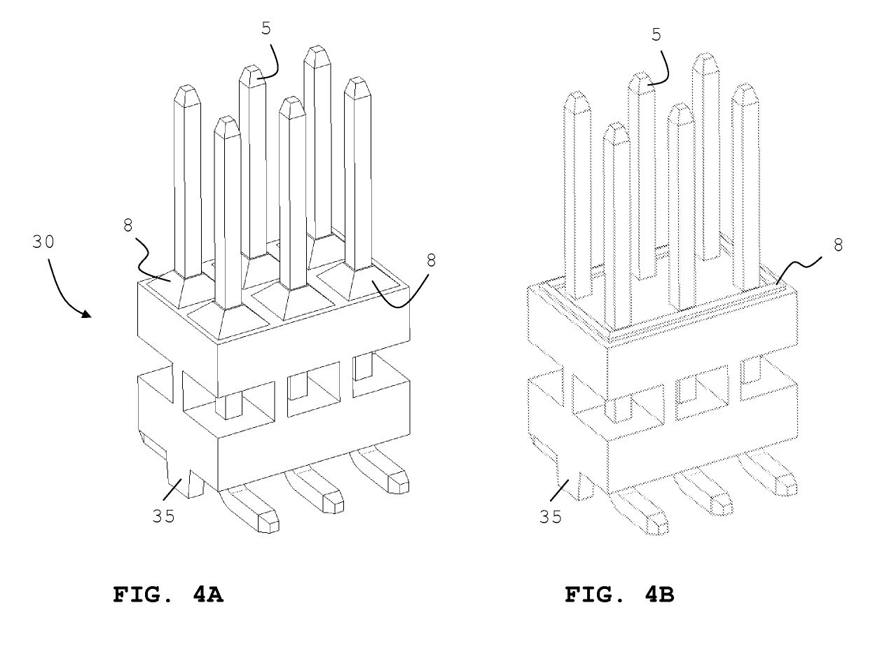

It should be noted that the structures 8, 9 configured for substantially closing the openings 2 may come in a variety of shapes. Exemplary embodiments are shown in FIGS. 4A and 4B.

In FIG. 4A, pyramid-shaped structures 8 are provided on frame 4 around each of the leads to interfere with corresponding structures in the openings 2. Closing each opening 2 individually is applicable if the pitch of the leads 5 is sufficiently large to allow a corresponding structure 8 around each lead.

Structures 8 surrounding multiple leads can be applied for smaller pitches. In FIG. 4B a rib 8 is provided on the frame 4 surrounding the set of leads 5. A corresponding recess (not shown) is provided at the first side of the first member 1 for cooperating with the rib to prevent moulding material to leak through openings 2 during the moulding step. However, the rib 8 may also abut against an otherwise flat surface of the first member 1. Alternatively, the rib 8 is provided on the first member 1.

Again, it should be noted that the header 30 and the second member 40 may be pressed, with a controlled pressure, against each other via the bent part of the pins or the stand-off structures 35 so as to avoid leaks of material 10 through the openings 2.

Both the structures of FIGS. 4A and 4B make sure that the openings 2 in first member 1 are closed around one or more of the one or more electrical leads 5, i.e. the moulding material does not contact the walls of the openings and, therefore, cannot leak into the openings 2 during moulding.

The invention provides an improved product and an economical and time shortened method for manufacturing an electrical product that reduces the probability the moulding material ends up in undesired places in the product.

1. An electric component comprising:
a first member comprising a first side and a second side, wherein said first member comprises one or more openings extending between said first side and said second side;
a body portion of moulding material provided on said first side of said first member;
a frame containing one or more electrical leads extending from said frame through said corresponding openings of said first member, wherein said first member and said frame cooperate to substantially close said openings around one or more of said one or more electrical leads.

2. The electric component according to claim 1, wherein said frame is at least partially contained in said body portion of moulding material at said first side of said first member.

3. The electric component according to claim 1, wherein said electric component comprises a second member provided at said first side of said first member and wherein said frame is provided between said first member and said second member to define a separation distance between said first member and said second member, said one or more leads extending from said second member to said second side of said first member.

4. The electric component according to claim 3, wherein said frame comprises one or more stand-off structures abutting against said second member.

5. The electric component according to claim 1, wherein said first member comprises first structures at each of said openings and said frame comprises second structures around each of said leads, wherein said first structures are configured for receiving said second structures to substantially close said openings around said one or more electrical leads.

6. The electric component according to claim 1, wherein said frame comprises a structure surrounding two or more of said leads and wherein said structure abuts against said first member.

7. The electric component according claim 1, wherein said frame comprises a first portion and a second portion interconnected by walls defining one or more spaces between said first and second portion and wherein said one or more leads extend through said first portion, said second portion and said spaces.

8. The electric component according claim 1, wherein said first member comprises a space at said second side exposing said one or more leads, said electric component further comprising one or more means configured for locking a connector having one or more electrical contacts corresponding with said one or more leads.

9. An electric component comprising:
a first member comprising a first side and a second side, wherein said first member comprises one or more openings extending between said first side and said second side;
a body portion of moulding material provided at said first side of said first member;
a frame containing one or more electrical leads extending from said frame through said corresponding openings of said first member, said frame being contained in said body portion of moulding material at said first side of said first member, wherein said first member and said frame have cooperating structures to substantially close said openings around one or more of said one or more electrical leads.

10. An electric component comprising:
a first member comprising a first side and a second side, wherein said first member comprises one or more openings extending between said first side and said second side;
a body portion of moulding material provided at said first side of said first member;
a frame containing one or more electrical leads extending from said frame through said corresponding openings of said first member, said frame being contained in said body portion of moulding material at said first side of said first member, wherein said frame comprises tapered structures around each of said leads and said openings are shaped for receiving said tapered structures to substantially close said openings around each of said one or more electrical leads.

11. A pin header configured for use in the electric component according to claim 1, the pin header comprising a frame containing one or more leads extending from said frame, wherein said frame comprises a first surface for facing a first member of said electric component and wherein the first surface comprises a structure configured for abutting against said first member.

12. The pin header according to claim 11, wherein structures are provided around each of said leads.

13. The pin header according to claim 11, wherein said frame comprises a first portion and a second portion interconnected by walls defining one or more open spaces between said first and second portion and wherein said one or more leads extend through said first portion, said second portion and said open spaces.

14. The pin header according to claim 11, wherein said frame comprises a second surface opposite to said first surface, said second surface comprising one or more stand-off structures.

15. A method of manufacturing an electric component comprising the steps of:
providing a first member comprising a first side and a second side, wherein said first member comprises one or more openings extending between said first side and said second side and one or more first structures surrounding all or each of said openings;
providing a frame containing one or more electrical leads extending from said frame, said frame comprising one or more second structures configured for cooperating with said one or more first structures;
positioning said frame at said first side of said first member such that said one or more leads extend through said corresponding openings of said first member and such that said first structures and said second structures cooperate to close one or more of said openings around one or more of said leads; and
providing a moulding material to obtain a body portion of moulding material at said first side of said first member by feeding said moulding material to accommodate said frame in said body portion.
